(19) United States
(12) Patent Application Publication
(10) Pub. No.: US 2025/0210525 A1
(43) Pub. Date: Jun. 26, 2025

(54) SEMICONDUCTOR DEVICE AND MANUFACTURING METHOD THEREOF

(71) Applicant: Kioxia Corporation, Tokyo (JP)

(72) Inventors: Genki SAWADA, Mie (JP); Mitsuhiko NODA, Kuwana (JP); Seiya HIRANO, Yokkaichi (JP)

(73) Assignee: Kioxia Corporation, Tokyo (JP)

(21) Appl. No.: 18/817,369

(22) Filed: Aug. 28, 2024

(30) Foreign Application Priority Data
Dec. 22, 2023 (JP) 2023-217351

(51) Int. Cl. H01L 23/532; G11C 16/04; H01L 23/528; H10B 43/10; H10B 43/27; H10B 43/35

(52) U.S. Cl. CPC H01L 23/53295; G11C 16/0483; H01L 23/5283; H10B 43/10; H10B 43/27; H10B 43/35

(57) ABSTRACT

A device includes first-lines located in a first direction of a first insulator. The first lines are arrayed in a second direction and extend in a third direction. Second insulators are located on the first-lines, respectively. The width of each of the second insulators in the second direction in a face in contact with a corresponding first-line is smaller than the width of the corresponding first-line. Third insulators are located correspondingly on the first-lines, respectively, and each coat both side surfaces of an associated one of the second insulators. A fourth insulator is located on the third insulators. A fifth insulator is located on the fourth insulator. A first contact penetrates through the second to fifth insulators to be connected to the first-lines. A second line is located on the first contact. The first contact, or the second and fourth insulators are located in the first direction of the first-lines.

### CROSS REFERENCE TO RELATED APPLICATIONS

This application is based upon and claims the benefit of priority from the prior Japanese Patent Application No. 2023-217351, filed on Dec. 22, 2023, the entire contents of which are incorporated herein by reference.

### FIELD

The embodiments of the present invention relate to a semiconductor device and manufacturing method thereof.

### BACKGROUND

Some of semiconductor storage devices such as a NAND flash memory have a three-dimensional memory cell array in which a plurality of memory cells are arranged three-dimensionally. With downscaling of a memory cell array, the interval between adjacent ones of a plurality of lines is narrowed. Accordingly, there is a risk of an increase in the parasitic capacitance between the lines and the parasitic capacitance between lines and via contacts.

### BRIEF DESCRIPTION OF THE DRAWINGS

FIG. 1 is a sectional view illustrating a configuration example of a semiconductor storage device according to a first embodiment;

FIG. 2 is a schematic plan view illustrating a stacked body;

FIG. 3 is a schematic sectional view illustrating memory cells of a three-dimensional structure;

FIG. 4 is a schematic sectional view illustrating the memory cells of a three-dimensional structure;

FIG. 5 is a sectional view illustrating a configuration example of bit lines of an array chip according to the first embodiment and the periphery thereof;

FIG. 6 is a sectional view illustrating one example of a manufacturing method of the array chip according to the first embodiment;

FIG. 7 is a sectional view illustrating one example of the manufacturing method of an array chip subsequent to FIG. 6;

FIG. 8 is a sectional view illustrating one example of the manufacturing method of an array chip subsequent to FIG. 7;

FIG. 9 is a sectional view illustrating one example of the manufacturing method of an array chip subsequent to FIG. 8;

FIG. 10 is a sectional view illustrating one example of the manufacturing method of an array chip subsequent to FIG. 9;

FIG. 11 is a sectional view illustrating one example of the manufacturing method of an array chip subsequent to FIG. 10;

FIG. 12 is a sectional view illustrating one example of the manufacturing method of an array chip subsequent to FIG. 11;

FIG. 13 is a sectional view illustrating one example of the manufacturing method of an array chip subsequent to FIG. 12;

FIG. 14 is a sectional view illustrating a configuration example of bit lines of an array chip according to a second embodiment and the periphery thereof;

FIG. 15 is a sectional view illustrating one example of a manufacturing method of the array chip according to the second embodiment;

FIG. 16 is a sectional view illustrating a configuration example of bit lines of an array chip according to a third embodiment and the periphery thereof;

FIG. 17 is a sectional view illustrating one example of a manufacturing method of an array chip according to a third embodiment;

FIG. 18 is a sectional view illustrating one example of the manufacturing method of an array chip subsequent to FIG. 17;

FIG. 19 is a sectional view illustrating one example of the manufacturing method of an array chip subsequent to FIG. 18;

FIG. 20 is a sectional view illustrating one example of the manufacturing method of an array chip subsequent to FIG. 19;

FIG. 21 is a sectional view illustrating one example of the manufacturing method of an array chip subsequent to FIG. 20;

FIG. 22 is a sectional view illustrating one example of the manufacturing method of an array chip subsequent to FIG. 21;

FIG. 23 is a sectional view illustrating a configuration example of bit lines of an array chip according to a fourth embodiment and a peripheral art thereof;

FIG. 24A is a sectional view illustrating one example of a manufacturing method of a semiconductor device according to a fifth embodiment;

FIG. 24B is a sectional view illustrating one example of the manufacturing method of a semiconductor device according to the fifth embodiment;

FIG. 25A is a sectional view illustrating one example of the manufacturing method of a semiconductor device subsequent to FIG. 24A;

FIG. 25B is a sectional view illustrating one example of the manufacturing method of a semiconductor device subsequent to FIG. 24B;

FIG. 26A is a sectional view illustrating one example of the manufacturing method of a semiconductor device subsequent to FIG. 25A;

FIG. 26B is a sectional view illustrating one example of the manufacturing method of a semiconductor device subsequent to FIG. 25B;

FIG. 27A is a sectional view illustrating one example of the manufacturing method of a semiconductor device subsequent to FIG. 26A;

FIG. 27B is a sectional view illustrating one example of the manufacturing method of a semiconductor device subsequent to FIG. 26B;

FIG. 28 is a sectional view illustrating one example of the manufacturing method of a semiconductor device subsequent to FIG. 27B;

FIG. 29 is a sectional view illustrating one example of the manufacturing method of a semiconductor device subsequent to FIG. 28;

FIG. 30 is a sectional view illustrating one example of the manufacturing method of a semiconductor device subsequent to FIG. 29;

FIG. 31A is a sectional view illustrating one example of the manufacturing method of a semiconductor device subsequent to FIG. 27A;

FIG. 31B is a sectional view illustrating one example of the manufacturing method of a semiconductor device subsequent to FIG. 30;

FIG. 32 is a sectional view illustrating a comparative example;

FIG. 33 is a block diagram illustrating a configuration example of a semiconductor storage device to which the array chip is applied; and

FIG. 34 is a circuit diagram illustrating one example of a circuit configuration of a memory cell array.

### DETAILED DESCRIPTION

In general, according to the embodiment, a semiconductor device comprises: a plurality of first lines located in a first direction with respect to a first insulating film. The first lines are arrayed in a second direction intersecting with the first direction and extending in a third direction intersecting with the first and second directions. A plurality of second insulating films are located correspondingly on the first lines, respectively. The width of each of the second insulating films in the second direction in a face in contact with a corresponding first line is smaller than the width of the corresponding first line in the second direction. A plurality of third insulating films are located correspondingly on the first lines, respectively, arrayed in the second direction, extend in the third direction, and each coat at least both side surfaces of an associated one of the second insulating films. A fourth insulating film is located on the third insulating films. A fifth insulating film is located on the fourth insulating film. A first contact penetrates through the second to fifth insulating films to be connected to any of the first lines. A second line is located on the first contact. The first contact or at least the second and fourth insulating films are located in the first direction of the first lines. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

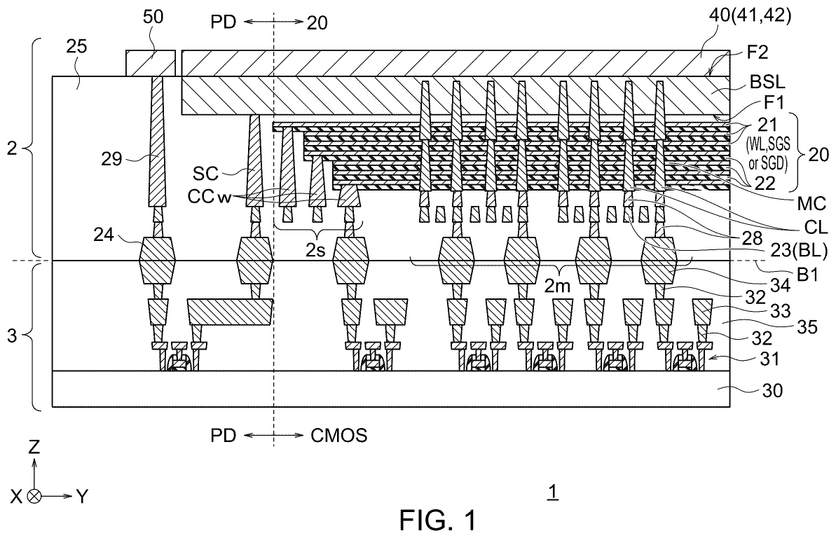

FIG. 1 is a sectional view illustrating a configuration example of a semiconductor storage device 1 according to a first embodiment. Hereinafter, the stacking direction of a stacked body 20 is assumed as a Z direction. One direction intersecting with, for example, being orthogonal to the Z direction is assumed as a Y direction. One direction intersecting with, for example, being orthogonal to the Z direction and the Y direction is assumed as an X direction. In the present specification, +Z directions are examples of a first direction, +X directions are examples of a third direction, and +Y directions are examples of a second direction.

The semiconductor storage device 1 includes an array chip 2 having a memory cell array, and a CMOS (Complementary Metal-Oxide Semiconductor) chip 3 having CMOS circuits. The array chip 2 and the CMOS chip 3 are bonded on a bonding face B1 and are electrically connected to each other with a line joined on the bonding face. FIG. 1 illustrates a state in which the array chip 2 is located on the CMOS chip 3.

The CMOS chip 3 includes a substrate 30, transistors 31, vias 32, lines 33 and 34, and an interlayer dielectric film 35.

The substrate 30 is, for example, a semiconductor substrate such as a silicon substrate. The transistors 31 are NMOS or PMOS transistors provided on the substrate 30. The transistors 31 constitute, for example, a CMOS circuit that controls the memory cell array of the array chip 2. A plurality of the transistors 31 constitute logic circuits such as a sense amplifier, a row decoder, and a column decoder. Semiconductor elements such as a resistive element and a capacitive element, other than the transistors 31 may be formed on the substrate 30.

Each of the vias 32 electrically connects between a transistor 31 and a line 33 or between a line 33 and a line 34. The lines 33 and 34 constitute a multilayer wiring structure in the interlayer dielectric film 35. The lines 34 are embedded in the interlayer dielectric film 35 and are exposed on the surface of the interlayer dielectric film 35 to be substantially flush with the surface. The lines 33 and 34 are electrically connected to the transistors 31 and the like. For example, a metal such as copper or tungsten is used as the vias 32, and the lines 33 and 34. The interlayer dielectric film 35 coats and protects the transistors 31, the vias 32, and the lines 33 and 34. For example, an insulating film such as a silicon dioxide film is used as the interlayer dielectric film 35.

The array chip 2 includes the stacked body 20, columnar bodies CL, slits ST (LI), a source layer BSL, a metallic layer 40, contact plugs CCw, contact plugs 29, bonding pads 50, and an interlayer dielectric film 25.

The stacked body 20 is provided above the transistors 31 and is positioned in the Z direction with respect to the substrate 30. The stacked body 20 is configured by alternately stacking a plurality of electrode films 21 and a plurality of insulating films 22 along the Z direction. The stacked body 20 constitutes the memory cell array. For example, a conductive metal such as tungsten is used as the electrode films 21. For example, an insulating film such as a silicon dioxide film is used as the insulating films 22. The insulating films 22 insulate the electrode films 21 from each other. That is, the electrode films 21 are stacked in a mutually insulated state. The numbers of stacked layers of the electrode films 21 and the insulating films 22 can be freely selected. The insulating films 22 may be, for example, porous insulating films or air gaps.

One or a plurality of the electrode films 21 at the top end and the bottom end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of memory cells MC. The source-side selection gates SGS are gate electrodes of source-side selection transistors. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region indicates a region of the stacked body 20 on a side far from the CMOS chip 3 (a side close to the metallic layer 40), and the lower region indicates a region of the stacked body 20 on a side close to the CMOS chip 3.

The semiconductor storage device 1 includes a plurality of memory cells MC connected in series between each of the source-side selection transistors and an associated drain-side selection transistor. A structure in which a source-side selection transistor, memory cells MC, and a drain-side selection transistor are connected in series is referred to as “memory string” or “NAND string”. A memory string is connected to, for example, a bit line BL through a via 28. The bit lines BL are lines 23 provided below the stacked body 20 and extending in the X direction (the depth direction of the drawing of FIG. 1). Therefore, the bit lines BL are hereinafter referred to also as “bit lines 23”.

A plurality of columnar bodies CL are provided in the stacked body 20. The columnar bodies CL extend in the stacked body 20 to penetrate through the stacked body 20 in the stacking direction (the Z direction) of the stacked body and are each located from vias 28 connected to a bit line 23 to the source layer BSL. An internal structure of the columnar bodies CL will be described later. In the present embodiment, each of the columnar bodies CL is formed in two tiers in the Z direction. However, there is no problem with the columnar bodies CL in one tier. Alternatively, each of the columnar bodies CL may be formed in three or more tiers.

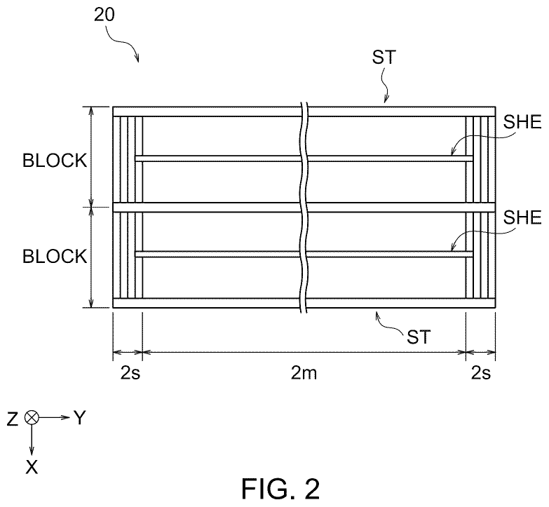

Although not illustrated in FIG. 1, a plurality of slits ST (see FIG. 2) are provided in the stacked body 20. The slits ST extend in the Y direction and penetrate through the stacked body 20 in the stacking direction (the Z direction) of the stacked body 20. An insulating film such as a silicon dioxide film is filled in each of the slits ST and the insulating film is configured in a plate shape. The slits ST electrically isolate the electrode films 21 of the stacked body 20. It is alternatively possible that the inner wall of each of the slits ST is coated with an insulating film such as a silicon dioxide film and that a conducting material is further embedded in the inner side of the insulating film. In this case, the conducting material can also function as a source line reaching the source layer BSL.

The source layer BSL is provided on the stacked body 20. The source layer BSL is an example of a first semiconductor layer. The source layer BSL is provided corresponding to the stacked body 20. The source layer BSL has a first face F1 and a second face F2 on the opposite side to the first face F1. The stacked body 20 (the memory cell array) is located on the side of the first face F1 of the source layer BSL, and the metallic layer 40 is located on the side of the second face F2 thereof. The metallic layer 40 includes a source line 41 and a power-supply line 42. The source layer BSL is connected in common to one ends of the columnar bodies CL and provides a plurality of columnar bodies CL in a same memory cell array 2m with a common source potential.

That is, the source layer BSL functions as a common source electrode of the memory cell array 2m. For example, a conductive material such as doped polysilicon is used for the source layer BSL. For example, a metallic material of a lower resistance than that of the source layer BSL, such as copper, aluminum, or tungsten is used for the metallic layer 40. A reference sign 2s denotes a stepped portion of the electrode films 21 provided to connect each of the contact plugs CCw to an electrode film 21. The stepped portion 2s will be described later with reference to FIG. 2.

Meanwhile, the bonding pads 50 are provided in a region that is above the stacked body 20 and where the source layer BSL is not located. The bonding pads 50 are connected to metallic wires or the like (not illustrated) and receive power supply or signals from outside the semiconductor storage device 1. The bonding pads 50 are provided so as to be connected to one ends of the contact plugs 29 in the Z direction. The bonding pads 50 are connected to the transistors 31 of the CMOS chip 3 via the contact plugs 29, the lines 24, and the lines 34. Accordingly, external power supplied from the bonding pads 50 is supplied to the transistors 31. Alternatively, signals are supplied to the transistors 31 or the memory cell array 2m via the bonding pads 50.

The contact plugs CCw are provided in a peripheral part of the stacked body 20 and extends in the Z direction in the interlayer dielectric film 25. Each of the contact plugs CCw is electrically connected between an electrode film 21 (a word line WL) and a line 24. The contact plugs CCw are provided at the stepped portions 2s each formed like stairs at each of the ends of the stacked body 20 and are each electrically connected to an associated electrode film 21. The contact plugs CCw are provided to transmit a word line voltage from the CMOS chip 3 to the associated electrode films 21. For example, a metal such as copper or tungsten is used for the contact plugs CCw.

The contact plugs 29 are provided in the peripheral part of the stacked body 20 and extend in the Z direction in the interlayer dielectric film 25. Each of the contact plugs 29 is a contact plug provided from a line 24 to a bonding pad 50. The contact plugs 29 are simultaneously formed in the same process as that of the contact plugs CCw connected to the word lines WL.

Each of the contact plugs 29 is electrically connected between a bonding pad 50 and a line 24. The contact plugs 29 are used to supply a power-supply voltage or a signal from the bonding pads 50 to the array chip 2 or the CMOS chip 3. For example, a metal such as copper or tungsten is used for the contact plugs 29. The power-supply voltage is, for example, a power-supply voltage VDD or a reference voltage (for example, a ground voltage) VSS lower than the power-supply voltage VDD. The signal may be a control signal from outside, or may be data to be written or read data.

In the present embodiment, the array chip 2 and the CMOS chip 3 are individually formed and are bonded on the boding face B1. Therefore, the transistors 31 are not provided in the array chip 2. The stacked body 20 (the memory cell array) is not provided in the CMOS chip 3. The transistors 31 and the stacked body 20 are both on the side of the first face F1 of the source layer BSL. The transistors 31 are located on the opposite side to the second face F2 where the metallic layer 40 is located.

The vias 28, the lines 23, and the lines 24 are provided below the stacked body 20. The lines 23 and 24 are embedded in the interlayer dielectric film 25. The lines 24 are exposed on the surface of the interlayer dielectric film 25 to be substantially flush with the surface. The lines 23 and 24 are electrically connected to semiconductor bodies 210 of the columnar bodies CL, and the like. For example, a metal such as copper or tungsten is used for the vias 28, the lines 23, and the lines 24. The interlayer dielectric film 25 coats and protects the stacked body 20, the vias 28, the lines 23, and the lines 24. For example, an insulating film such as a silicon dioxide film is used as the interlayer dielectric film 25.

The interlayer dielectric film 25 and the interlayer dielectric film 35 are bonded on the bonding face B1. Associated therewith, the lines 24 and the lines 34 are joined on the bonding face B1 to be substantially flush therewith. Accordingly, the array chip 2 and the CMOS chip 3 are electrically connected to each other via the lines 24 and the lines 34.

FIG. 2 is a schematic plan view illustrating the stacked body 20. The stacked body 20 includes the stepped portions 2s and the memory cell array 2m. The stepped portions 2s are located, for example, at the ends of the stacked body 20. The memory cell array 2m is sandwiched or surrounded by the stepped portions 2s. The slits ST (LI) are provided from the stepped portion 2s at one end of the stacked body 20 through the memory cell array 2m to the stepped portion 2s at the other end of the stacked body 20. Slits SHE are provided at least on the memory cell array 2m. The slits SHE are shallower in the Z direction than the slits ST (LI) and extend substantially in parallel to the slits ST (LI). The slits SHE electrically isolate the electrode films 21 for each of the drain-side selection gates SGD. The slits ST may be source lines LI electrically isolated from the electrode films 21 of the stacked body 20 while being electrically connected to the source layer BSL. That is, the slits ST may be source lines LI electrically isolated from the electrode films 21 of the stacked body 20 constituting the memory cell array and electrically connected to the source layer BSL.

A portion of the stacked body 20 sandwiched by two slits ST illustrated in FIG. 2 is referred to as “block (BLOCK)”. A block constitutes, for example, a minimum unit of data erasing. A slit SHE is provided in each block. The stacked body 20 between a slit ST and a slit SHE is referred to as “finger”. The drain-side selection gates SGD are divided for each finger. Accordingly, at the time of writing and reading data, one finger in one block can be brought to a selected state by the associated drain-side selection gate SGD.

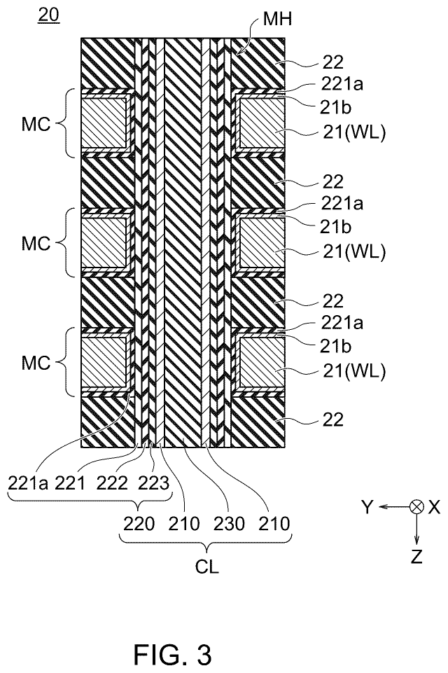

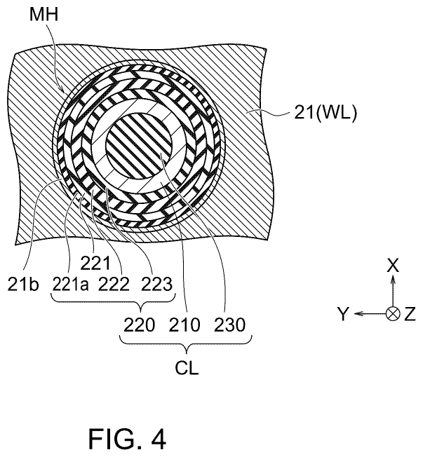

FIGS. 3 and 4 are schematic sectional views illustrating memory cells of a three-dimensional structure. Each of the columnar bodies CL is provided in a memory hole MH formed in the stacked body 20. Each of the columnar bodies CL penetrates through the stacked body 20 along the Z direction from one end part of the stacked body 20 to be provided in the stacked body 20 and the source layer BSL. Each of the columnar bodies CL includes the semiconductor body 210, a memory film 220, and a core layer 230. Each columnar body CL includes the core layer 230 located at a central part thereof, the semiconductor body (a semiconductor member) 210 located around the core layer 230, and the memory film 220 located around the semiconductor body 210. The semiconductor body 210 extends in the stacked body 20 in the stacking direction (the Z direction). The semiconductor body 210 is electrically connected to the source layer BSL. The memory film 220 is located between the semiconductor body 210 and the electrode films 21 and has charge capturing parts. A plurality of the columnar bodies CL each selected from each of the fingers are connected in common to one bit line 23 through the vias 28 in FIG. 1. Each of the columnar bodies CL is provided, for example, in a region of the memory cell array 2m.

As illustrated in FIG. 4, the shape of each of the memory holes MH in an X-Y plane is, for example, circular or elliptic. A block dielectric film 221a constituting a part of the memory film 220 may be provided between each of the electrode films 21 and adjacent insulating films 22. The block dielectric film 221a is, for example, a silicon oxide or a metal oxide. One example of the metal oxide is an aluminum oxide. A barrier film 21b may be provided between each of the electrode films 21 and adjacent insulating films 22 and between each of the electrode films 21 and the memory film 220. The barrier film 21b is, for example, a stacked film including titanium nitride and titanium, for example, in a case in which the electrode films 21 are tungsten. The block dielectric film 221a suppresses back tunneling of charges from the electrode films 21 to the memory film 220. The barrier film 21b improves adhesion between the electrode films 21 and the block dielectric film 221a.

The shape of the semiconductor body 210 is, for example, a bottomed tube. For example, polysilicon is used as the semiconductor body 210. The semiconductor body 210 is, for example, undoped silicon. The semiconductor body 210 may be p-type silicon. The semiconductor body 210 functions as channels of the drain-side selection transistors, the memory cells MC, and the source-side selection transistors. That is, a plurality of the memory cells MC each have a storage region between the semiconductor body 210 and an electrode film 21 functioning as a word line WL and are stacked in the Z direction. One ends of a plurality of the semiconductor bodies 210 in the same memory cell array 2m are electrically connected in common to the source layer BSL.

The memory film 220 includes, for example, a cover dielectric film 221, a charge capturing film 222, a tunnel dielectric film 223, and the block dielectric film 221a. A portion of the memory film 220 other than the block dielectric film 221a is located between the inner wall of the memory hole MH and the semiconductor body 210. The shape of the memory film 220 is, for example, tubular. Each of the charge capturing film 222 and the tunnel dielectric film 223 extends in the Z direction.

The cover dielectric film 221 is located between the insulating films 22 and the charge capturing film 222 and between the block dielectric film 221a and the charge capturing film 222. The cover dielectric film 221 includes, for example, a silicon oxide. The cover dielectric film 221 protects the charge capturing film 222 from being etched when sacrificial films (not illustrated) are replaced by the electrode films 21 (in a replacement process). When the replacement process is not used to form the electrode films 21, it is possible that the cover dielectric film 221 is not provided.

The charge capturing film 222 is located between the cover dielectric film 221 and the tunnel dielectric film 223. The charge capturing film 222 includes, for example, a silicon nitride and has a trap site that traps charges in the film. Portions of the charge capturing film 222 sandwiched between the electrode films 21 functioning as the word lines WL and the semiconductor body 210 constitute the storage regions of the memory cells MC as the charge capturing parts. A threshold voltage of each of the memory cells MC varies according to whether there are charges in the associated charge capturing part or the amount of charges captured in the charge capturing part. This causes each of the memory cells MC to retain information.

The tunnel dielectric film 223 is located between the semiconductor body 210 and the charge capturing film 222. The tunnel dielectric film 223 includes, for example, a silicon oxide, or a silicon oxide and a silicon nitride. The tunnel dielectric film 223 is a potential barrier between the semiconductor body 210 and the charge capturing film 222. For example, when electrons are injected from the semiconductor body 210 to the charge capturing film 222 (a write operation) and when positive holes are injected from the semiconductor body 210 to the charge capturing film 222 (an erase operation), the electrons and the positive holes each pass through (tunnel) the potential barrier of the tunnel dielectric film 223.

The core layer 230 fills the internal space of the tubular semiconductor body 210. The shape of the core layer 230 is, for example, columnar. The core layer 230 includes, for example, a silicon oxide and is insulative.

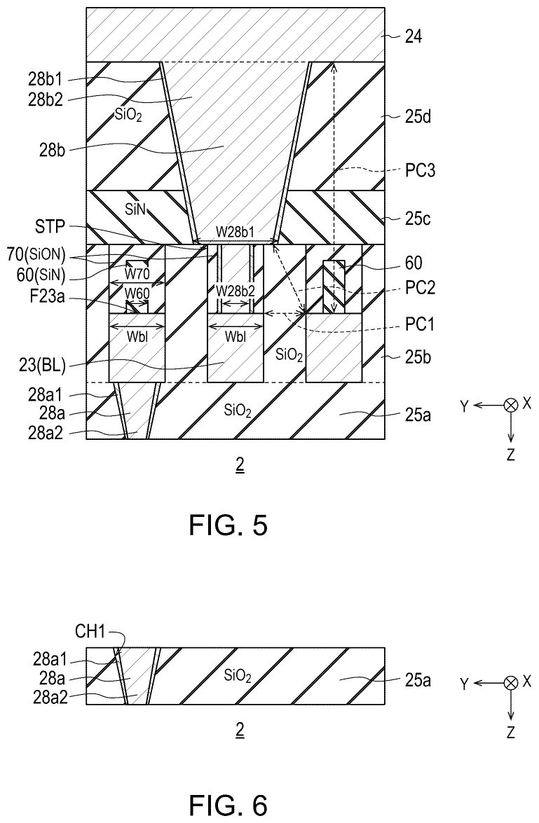

FIG. 5 is a sectional view illustrating a configuration example of the bit lines of the array chip according to the first embodiment and the periphery thereof. FIG. 5 illustrates a configuration in which the upper side and the lower side in FIG. 1 are inverted. Therefore, the configuration is described with the −Z direction as upward. FIG. 5 illustrates a configuration of a part above (in the −Z direction) the columnar bodies CL and illustrations of the configuration of the columnar bodies CL and below the columnar bodies CL are omitted.

The array chip 2 includes insulating films 25a to 25d, via contacts 28a, the bit lines 23 (BL), insulating films 60 and 70, via contacts 28b, and the lines 24.

The insulating film 25a is located above the stacked body 20 and the columnar bodies CL. For example, an insulating material such a silicon dioxide film is used as the insulating film 25a.

The via contacts 28a are embedded in the insulating film 25a. The via contacts 28a are provided to penetrate through the insulating film 25a from the top surface of the insulating film 25a in the Z direction to the bottom surface thereof. The via contacts 28a each electrically connect between the semiconductor body 210 of the associated columnar body CL and a bit line 23. Each of the via contacts 28a includes a barrier metal 28a1, and a contact body 28a2 embedded in the inner side of the barrier metal. For example, a conductive metallic material such as a titanium film or a titanium nitride film is used as the barrier metal. For example, a conductive metallic material such as tungsten is used for the contact body.

The insulating film 25b is located on the insulating film 25a. The insulating film 25b is located between adjacent ones of the bit lines 23 and between adjacent ones of the insulating films 70. For example, an insulating material such as a silicon dioxide film is used as the insulating film 25b.

The bit lines 23 are provided in the −Z direction with respect to the insulating film 25a and are embedded in the insulating film 25b. The bit lines 23 extend in the X direction on the top surface of the insulating film 25a and are arrayed in the Y direction. For example, a conductive metallic material such as tungsten or copper is used for the bit lines 23.

A plurality of insulating films 60 are provided in a region of top surfaces of the bit lines 23 with which the via contacts 28b are not in contact. The insulating films 60 are in contact with top surfaces F23a of the corresponding bit lines 23, respectively. In a contact face between an insulating film 60 and the corresponding bit line 23, a width W60 of the insulating film 60 in the Y direction is smaller than a width Wb1 of the corresponding bit line 23 in the Y direction. A material film including silicon and nitrogen is used for the insulating films 60 and, for example, an insulating material such as a silicon nitride film is used therefor.

A plurality of insulating films 70 are provided corresponding to regions of the bit lines 23, respectively. On the bit lines 23 for which the via contacts 28b are not provided, the insulating film 70 is provided to coat the top surface and the side surfaces of each of the insulating films 60. That is, each of the insulating films 70 has an inverted U-shape and coats the insulating film 60. The insulating film 70 is provided also on the side surfaces of the via contacts 28b located between adjacent ones of the insulating films 60. The insulating film 70 is located between the insulating films 60 and the insulating film 25c. On a contact face between an insulating film 70 and a bit line 23, a width W70 of the insulating film 70 in the Y direction is substantially the same as the width Wb1 of the corresponding bit line 23 in the Y direction. A material film including silicon, oxygen and nitrogen is used for the insulating film 70 and, for example, an insulating material such as silicon oxynitride film is used therefor. The insulating films 60 and 70 are different materials having different etching selectivities from each other. Accordingly, either one of the insulating film 60 and the insulating film 70 can be selectively etched. The insulating film 70 is a (Low-k) material being lower in the relative permittivity than the insulating film 60.

The insulating film 25d is provided on the insulating film 25c. The insulating films 25c and 25d are different materials having different etching selectivities from each other. Therefore, the insulating film 25c functions as an etching stopper at the time of forming contact holes in the insulating film 25d. For example, an insulating material such as a silicon nitride film is used as the insulating film 25c. As the insulating film 25d, an insulating material such as a silicon dioxide film is used.

The via contacts 28b are embedded in the insulating films 25c and 25d. The via contacts 28b penetrate through parts of the insulating films 60 and 70 to be connected to the bit lines 23. The via contacts 28b are provided to penetrate through the insulating films 25d, 25c, and 60 from the top surface of the insulating film 25d to the bottom surface of the insulating film 60. Each of the via contacts 28b electrically connects between a line 24 and an associated bit line 23. Accordingly, each of the lines 24 can be electrically connected to any of the bit lines 23 through a via contact 28b. The via contacts 28b can be substantially circular, substantially elliptic, or substantially polygonal in a planar view seen from the Z direction. Therefore, the insulating films 60 and 70 are located on the bit lines 23 in a region other than the formation region of the via contacts 28b. That is, in the Z direction of each of the bit lines 23, a via contact 28b is provided or at least the insulating films 60 and 70 are provided. Each of the via contacts 28b includes the barrier metal 28b1 and the contact body 28b2 embedded in the inner side of the barrier metal. For example, a conductive metallic material such as a titanium film or a titanium nitride film is used as the barrier metal. For example, a conductive metallic material such as tungsten is used as the contact body.

Each of the via contacts 28b is formed in a self-aligned manner in the insulating film 25c and the insulating films 70 and 60. Therefore, each of the via contacts 28b has a step STP at the same height as that of the bottom surface of the insulating film 25c. A width W28b1 of each of the via contacts 28b in the X or Y direction at the same height as that of the bottom surface of the insulating film 25c is larger than a width W28b2 of the via contact 28b in the X or Y direction on a connection face with the associated bit line 23. The width W28b2 is smaller than the width Wb1 of the bit line 23 in the Y direction. The width W28b1 of each of the via contacts 28b in the X or Y direction gradually decreases from the line 24 to the bit line 23 and becomes narrower and thinner to the width W28b2 at the step STP on the bottom surface of the insulating film 25c. The via contact 28b with the width W28b2 is sandwiched by the insulating films 70 on the both side surfaces. The width increases to Wb1 on the bit line 23. As described above, each of the via contacts 28b is configured like the neck of a bottle between the insulating films 70.

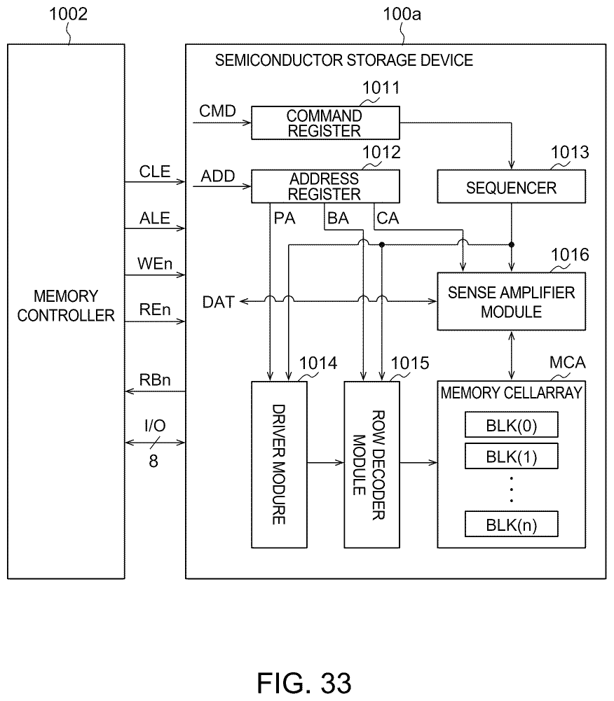

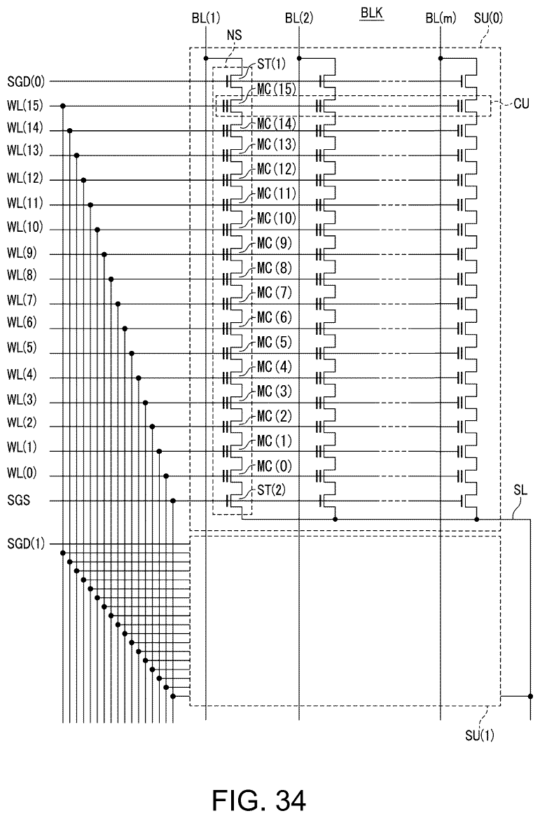

Each of the lines 24 is provided on the associated via contact 28b and the insulating film 25d. Each of the lines 24 applies power to the semiconductor body 210 of the associated columnar body CL through the associated bit line BL. The lines 24 are electrically connected to a sense amplifier module (see FIG. 33) and transmit a signal voltage based on data read from memory cells MC to the sense amplifier module. For example, a conductive metallic material such as tungsten or copper is used as the lines 24.

In the array chip 2 according to the present embodiment, the insulating films 60 and 70 are provided on the bit lines 23 in a region where the via contacts 28b are not provided. As described above, the insulating film 70 is, for example, a silicon oxynitride film and is lower in the relative permittivity than the insulating film 60 (for example, a silicon nitride film). The insulating film 60 is coated with the insulating film 70 lower in the relative permittivity. Therefore, a parasitic capacitance PC1 between adjacent bit lines 23, a parasitic capacitance PC2 between each via contact 28b and the associated bit line 23, and a parasitic capacitance PC3 between each line 24 and the associated bit line 23 are decreased relative to a case in which the insulating film 70 is not provided. It is considered that the parasitic capacitance PC1 between adjacent bit lines 23 decreases due to the insulating film 70 in view of also a capacitance caused by sneaking from one of the bit lines 23 to the top surface of the other bit line 23.

With decrease of the parasitic capacitance PC1 between adjacent bit lines 23, the parasitic capacitance PC2 between each via contact 28b and the associated bit line 23, and the parasitic capacitance PC3 between each line 24 and the associated bit line 23, the interval between arrays of the bit lines 23 in the Y direction can be narrowed. The interval between each bit line 23 and the associated via contact 28b, and the interval between each bit line 23 and the associated line 24 can also be narrowed. This leads to downscaling of the array chip 2.

A manufacturing method of the array chip 2 according to the present embodiment is explained next.

FIGS. 6 to 13 are sectional views illustrating one example of the manufacturing method of an array chip according to the first embodiment.

First, a structure under the insulating film 25a, such as the stacked body 20 and the columnar bodies CL, is formed.

Next, as illustrated in FIG. 6, the insulating film (for example, a silicon dioxide film) 25a is deposited on the stacked body 20 and the columnar bodies CL. Next, contact holes CH1 to the columnar bodies CL are formed using a lithography technique and an etching technique. Next, the barrier metal (for example, a stacked film including titanium and titanium nitride) 28al is formed on the inner wall of each of the contact holes CH1, and the material (for example, tungsten) of the contact body 28a2 is embedded in the inner side of the barrier metal. Accordingly, the via contacts 28a illustrated in FIG. 6 are formed to penetrate through the insulating film 25a. Each of the via contacts 28a penetrates through the insulating film 25a and is electrically connected to the semiconductor body 210 of any of the columnar bodies CL.

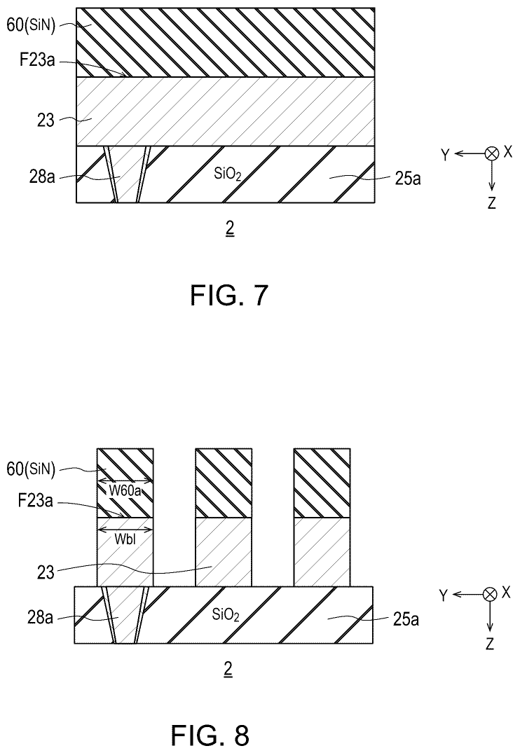

Next, as illustrated in FIG. 7, the material (for example, tungsten) of the bit lines 23 is deposited on the insulating film 25a (in the −Z direction). The material (for example, a silicon nitride film) of the insulating film 60 is deposited on the surface F23a of the material of the bit lines 23.

Next, the material of the insulating film 60 is processed using a lithography technique and an etching technique. Next, the material of the bit lines 23 is processed using the insulating film 60 as a mask. Accordingly, the bit lines 23 and the insulating films 60 arrayed in the Y direction and extending in the X direction are formed as illustrated in FIG. 8. Each of the insulating films 60 is located on the top surface F23a of the corresponding bit line 23. A width W60a of each of the insulating films 60 in the Y direction on a contact face between the insulating film 60 and the corresponding bit line 23 is substantially equal to the width Wb1 of the bit line 23 in the Y direction.

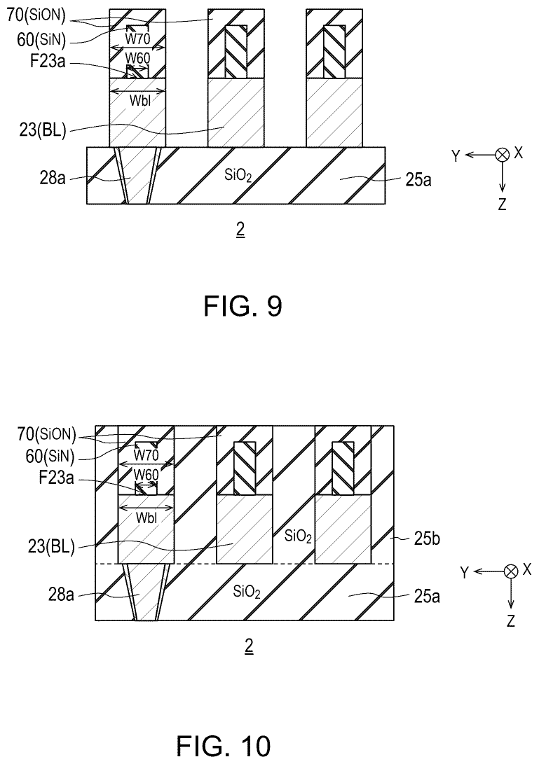

Next, as illustrated in FIG. 9, the insulating film 70 is formed on the top surface and the both side surfaces of each of the insulating films 60 by oxidizing the surfaces of the insulating films 60. That is, exposed faces (the top surface and the both side surfaces) of each of the insulating films 60 are oxidized to become the insulating film 70. For example, when the insulating film 60 is a silicon nitride film, the insulating film 70 is a silicon oxynitride film or a mixed film including a silicon dioxide film and a silicon oxynitride film. A silicon dioxide film is a material lower in the relative permittivity than a silicon nitride film. At this time, a width W70 of each insulating film 70 in the Y direction is substantially equal to the width Wb1 of each bit line 23 in the Y direction. However, the width W60 of each insulating film 60 in the Y direction is smaller than the width Wb1 of each bit line 23 in the Y direction.

Next, the material of the insulating film (for example, a silicon dioxide film) 25b is deposited between adjacent ones of the bit lines 23 and between adjacent ones of the insulating films 70. Next, the insulating film 25b is polished using a CMP (Chemical Mechanical Polishing) method until the surfaces of the insulating films 70 are exposed. Accordingly, the insulating film 25b is embedded between adjacent ones of the bit lines 23 and between adjacent ones of the insulating films 70 as illustrated in FIG. 10.

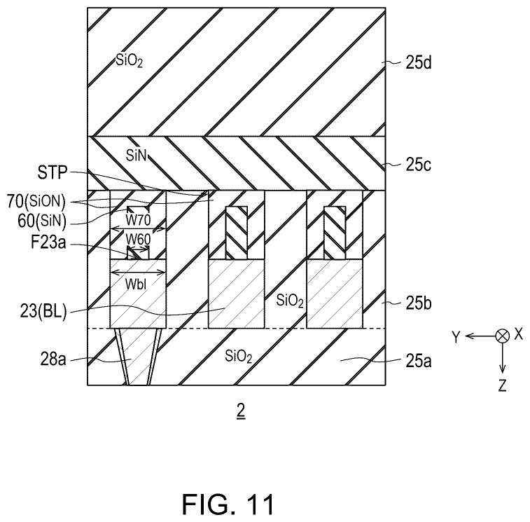

Next, as illustrated in FIG. 11, the insulating film (for example, a silicon nitride film) 25c is deposited on the insulating films 25b and 70. The insulating film (for example, a silicon dioxide film) 25d is further deposited on the insulating film 25c.

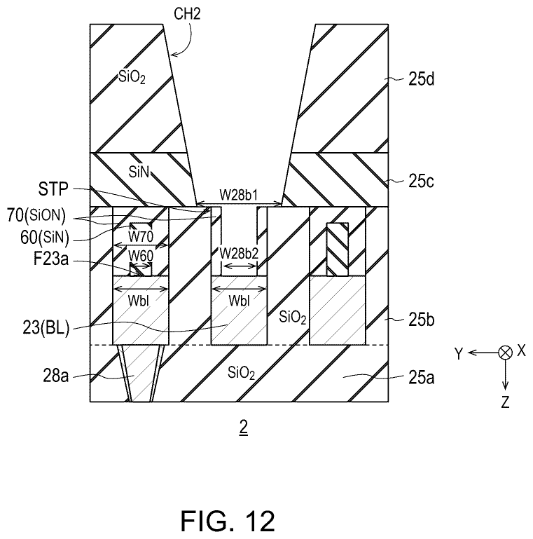

Next, the insulating film 25d is processed using a lithography technique and an etching technique. At that time, the insulating film 25c functions as an etching stopper. Subsequently, the insulating film 25c is etched using the insulating film 25d as a mask. Further, the insulating films 70 are etched in a self-aligned manner with respect to the insulating film 25b according to a difference in the etching selectivity between the insulating films 70 and the insulating film 25b. Accordingly, the steps STP are generated. After the insulating films 70 are etched, the insulating films 60 are etched in a self-aligned manner and selectively with respect to the insulating films 70. Contact holes CH2 are thereby formed in the formation region of the via contacts 28b as illustrated in FIG. 12. Each of the contact holes CH2 penetrates through the insulating films 25d, 25c, 70, and 60 to reach the top surface F23a of the associated bit line 23.

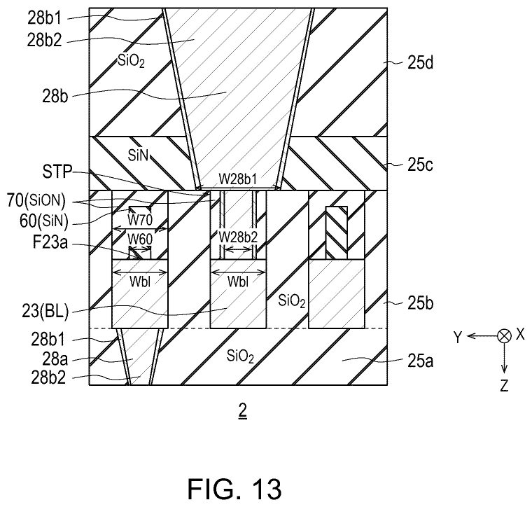

Next, the barrier metal (for example, a stacked film including titanium and titanium nitride) 28b1 is formed on the inner wall of each of the contact holes CH2 and the material (for example, tungsten) of the contact body 28b2 is embedded in the inner side of the barrier metal 28b1. Accordingly, the via contacts 28b illustrated in FIG. 13 are formed so as to penetrate through the insulating films 25d, 25c, 70, and 60 to be connected to the top surfaces F23a of the associated bit lines 23, respectively. Each of the via contacts 28b is electrically connected to the semiconductor body 210 of any of the columnar bodies CL via the associated bit line 23. Meanwhile, the insulating films 25d, 25c, 60, and 70 are left on the bit lines 23 in a region where the contact holes CH2 are not provided.

In the formation process of the contact holes CH2, the insulating films 60 are etched in a self-aligned manner and selectively. Therefore, each of the via contacts 28b has the step STP at the same height (height in the Z direction) as the bottom surface of the insulating film 25c or the top surfaces of the insulating films 25c and 70. The insulating film 70 is provided in a tubular manner around each of the via contacts 28b between the step STP and the associated bit line 23.

Next, as illustrated in FIG. 5, the lines 24 are formed on the via contacts 28b and the insulating film 25d. Accordingly, the configuration of the array chip 2 illustrated in FIG. 5 is obtained.

### Second Embodiment

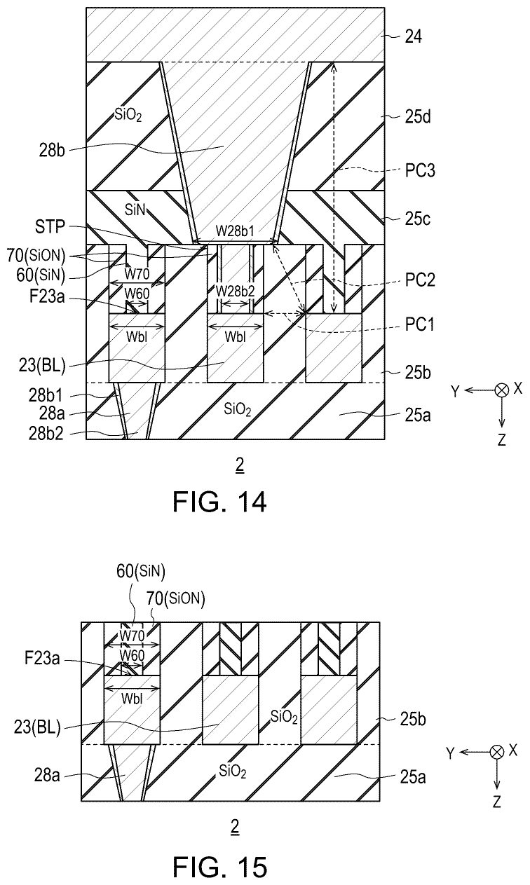

FIG. 14 is a sectional view illustrating a configuration example of bit lines of an array chip according to a second embodiment and the periphery thereof. In the second embodiment, the insulating film 70 (for example, a silicon oxynitride film or a mixed film including a silicon dioxide film and a silicon oxynitride film) is not provided on the insulating films 60 (for example, a silicon nitride film). Therefore, the insulating film 25c coats the top surface of each of the insulating films 60 to be in contact with the insulating film 70 in the region where the via contacts 28b are not provided. The insulating film 70 is provided on the both side surfaces of each of the insulating films 60. Other configurations of the second embodiment may be identical to those of the first embodiment. Accordingly, the second embodiment can exert identical effects as those of the first embodiment.

FIG. 15 is a sectional view illustrating one example of the manufacturing method of an array chip according to the second embodiment. To obtain the array chip 2 according to the second embodiment, after the processes explained with reference to FIGS. 6 to 9 are performed, the insulating film 70 is overpolished until the top surfaces of the insulating films 60 are exposed during polishing of the insulating film 25b by a CMP method in the process illustrated in FIG. 10. A structure illustrated in FIG. 15 is thereby obtained. Subsequently, the processes explained with reference to FIGS. 11 to 13 are performed, whereby the configuration of the array chip 2 illustrated in FIG. 14 is obtained.

### Third Embodiment

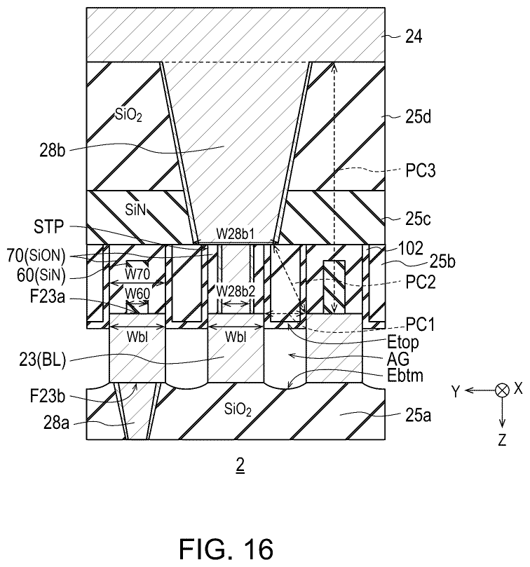

FIG. 16 is a sectional view illustrating a configuration example of bit lines of an array chip according to a third embodiment and the periphery thereof. In the third embodiment, an air gap AG is provided between adjacent ones of the bit lines 23. Top ends Etop of the air gaps AG are located below (in the +Z direction) the top surfaces F23a of the bit lines 23. Bottom ends Ebtm of the air gaps AG are located below the bottom surfaces F23b of the bit lines 23.

The air gaps AG are lower in the relative permittivity than the insulating film 25b. Therefore, the parasitic capacitance PC1 between adjacent ones of the bit lines 23 can be further decreased. With the bottom ends Ebtm of the air gaps AG lower than the bottom surfaces F23b of the bit lines 23, the parasitic capacitance PC1 between adjacent ones of the bit lines 23 can be further decreased. Furthermore, the top ends Etop of the air gaps AG are lower than the top surfaces F23a of the bit line 23. This is to suppress penetration of the material of the via contacts 28b into the air gaps AG in the formation process of the via contacts 28b as will be described below.

Other configurations of the third embodiment may be identical to those of the first embodiment. Accordingly, the third embodiment can exert identical effects as those of the first embodiment. The third embodiment may be combined with the second embodiment.

A manufacturing method of the array chip 2 according to the third embodiment is explained next.

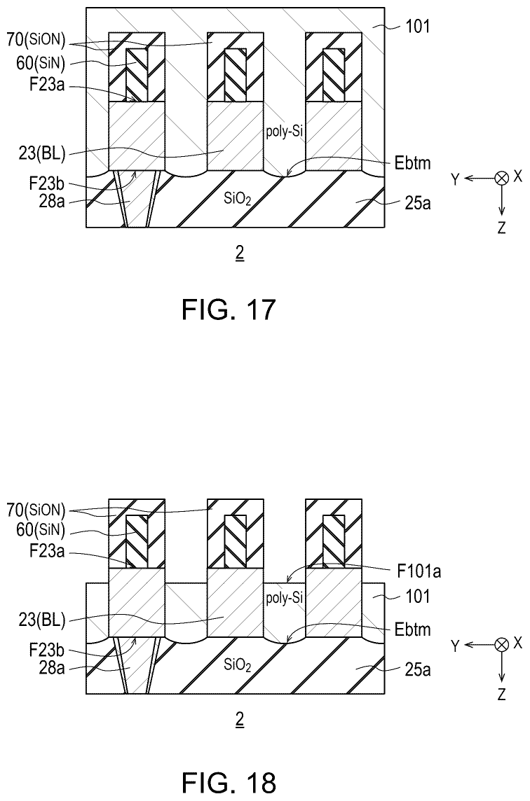

FIGS. 17 to 22 are sectional views illustrating one example of the manufacturing method of an array chip according to the third embodiment.

After the processes explained with reference to FIGS. 6 to 9 are performed, a sacrificial film 101 (for example, polysilicon) is deposited between adjacent ones of the bit lines 23 and between adjacent ones of the insulating films 70 as illustrated in FIG. 17. At the time of processing of the bit lines 23 in the process explained with reference to FIG. 8, the insulating film 25a between adjacent ones of the bit lines 23 is gouged by overetching. Therefore, the bottom end Ebtm of the sacrificial film 101 is located below (in the +Z direction) the bottom surfaces F23b of the bit lines 23.

Next, as illustrated in FIG. 18, the sacrificial film 101 is etched back to cause the top surface F101a of the sacrificial film 101 to be located below (in the +Z direction) the top surfaces F23a of the bit lines 23.

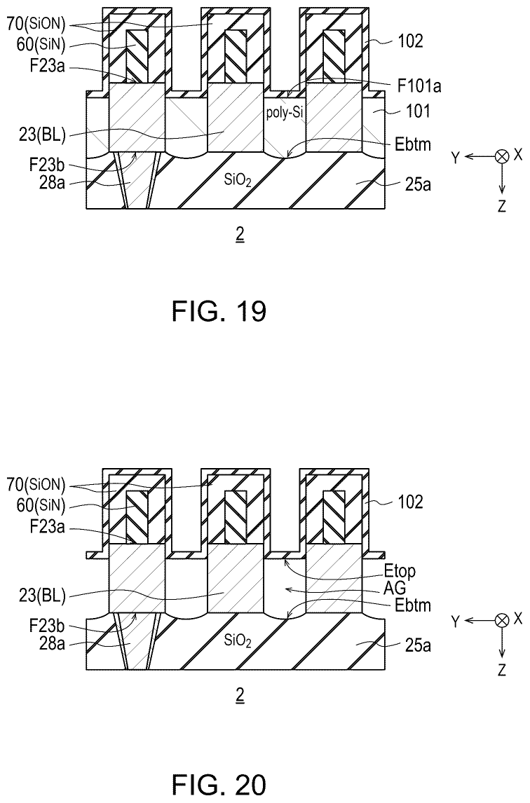

Next, as illustrated in FIG. 19, a cap film (for example, a silicon dioxide film) 102 is formed to coat the insulating film 70 and the sacrificial film 101.

Next, as illustrated in FIG. 20, the sacrificial film 101 is selectively etched to form the air gaps AG between the cap film 102 and the bit lines 23. At that time, the top ends Etop of the air gaps AG are located below the top surfaces F23a of the bit lines 23 and the bottom ends Ebtm thereof are located below the bottom surfaces F23b of the bit lines 23.

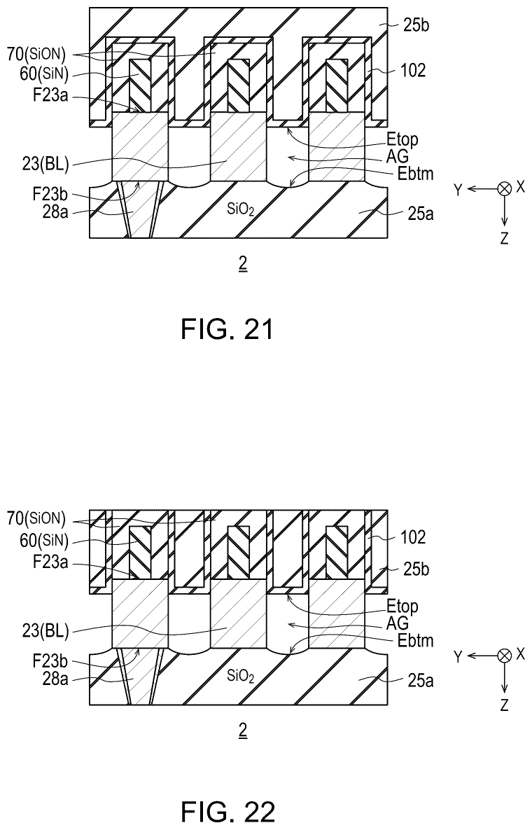

Next, as illustrated in FIG. 21, the material of the insulating film 25b is deposited on the cap film 102. At that time, the cap film 102 suppresses penetration of the material of the insulating film 25b into the air gaps AG and maintains the air gaps AG.

Next, as illustrated in FIG. 22, the insulating film 25b is polished using a CMP method until the insulating film 70 is exposed.

Subsequently, the processes explained with reference to FIGS. 11 to 13 are performed, whereby the configuration of the array chip 2 illustrated in FIG. 16 is obtained.

In a case in which the top ends Etop of the air gaps AG are at a position equal to or higher than (located in the −Z direction relative to) the top surfaces F23a of the bit lines 23, there is a possibility that the contact holes CH2 penetrate through the insulating films 70 to be communicated with the air gaps AG during formation of the contact holes CH2 in FIG. 12. In this case, the material of the via contacts 28b adversely penetrates into the air gaps AG in the formation process of the via contacts 28b.

Therefore, in the third embodiment, to suppress penetration of the material of the via contacts 28b into the air gaps AG, the top ends Etop of the air gaps AG are located at a position lower (in the +Z direction) than the top surfaces F23a of the bit lines 23. The position of the top ends Etop of the air gaps AG is adjusted to a height position of the top surface F101a of the sacrificial film 101 illustrated in FIG. 18. With adjustment of the top surface F101a of the sacrificial film 101 to be lower than the top surfaces F23a of the bit lines 23, the top ends Etop of the air gaps AG are positioned lower than the top surfaces F23a of the bit lines 23. Accordingly, penetration of the material of the via contacts 28b into the air gaps AG can be suppressed.

### Fourth Embodiment

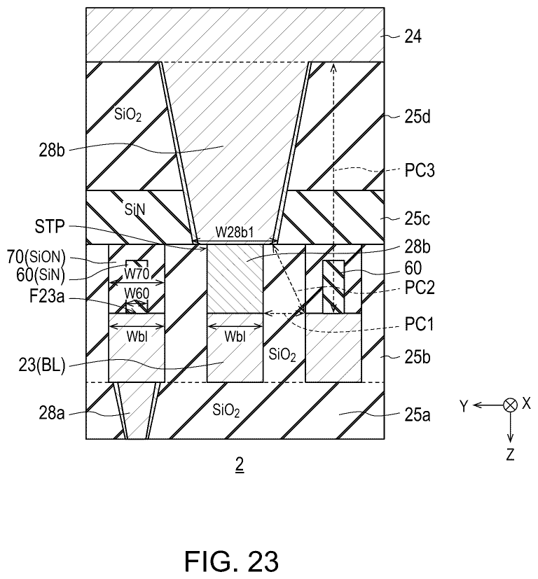

FIG. 23 is a sectional view illustrating a configuration example of bit lines of an array chip according to a fourth embodiment and the periphery thereof. In the fourth embodiment, the insulating film 70 is not provided on the side surfaces of each of the via contacts 28b in the Y direction in a region of the bit lines 23 with which the via contacts 28b are in contact. Each of the via contacts 28b is provided entirely on the associated bit line 23 in the Y direction.

Other configurations of the fourth embodiment may be identical to those of the first embodiment. Accordingly, the fourth embodiment can exert identical effects as those of the first embodiment. The fourth embodiment may be combined with the second or third embodiment. In this case, the fourth embodiment can exert identical effects as those of the second or third embodiment.

In a manufacturing method of a semiconductor device according to the fourth embodiment, it suffices that the insulating film 70 located in a lower part of each of the contact holes CH2 is removed along with the insulating film 60 in the formation process of the contact holes CH2 illustrated in FIG. 12. Other processes in the fourth embodiment may be identical to those of the manufacturing process in the first embodiment.

### Fifth Embodiment

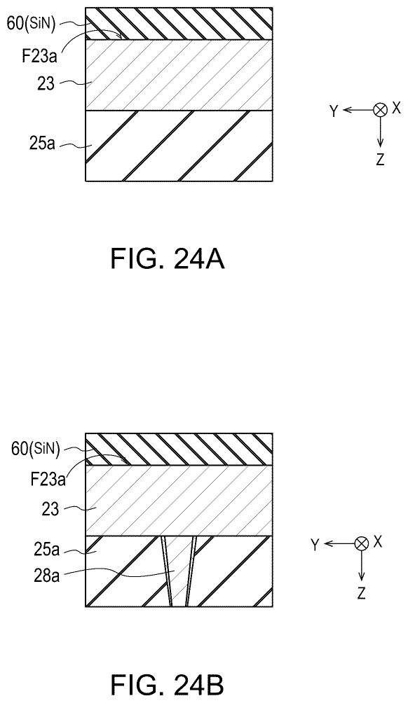

FIGS. 24A to 31B are sectional views illustrating one example of a manufacturing method of a semiconductor device according to a fifth embodiment. FIGS. 24A, 25A, 26A, 27A, and 31A illustrate formation processes of the via contacts 28b in a peripheral region PD in FIG. 1. FIGS. 24B, 25B, 26B, 27B, 28 to 30, and 31B illustrate formation processes of the via contacts 28b in the stacked body 20 in FIG. 1.

The via contacts 28a are formed in the insulating film 25a through the process explained with reference to FIG. 6. Next, as illustrated in FIGS. 24A and 24B, the material (for example, tungsten) of the bit lines 23 is deposited on the insulating film 25a (in the −Z direction). The material (for example, a silicon nitride film) of the insulating film 60 is deposited on the surface F23a of the material of the bit lines 23.

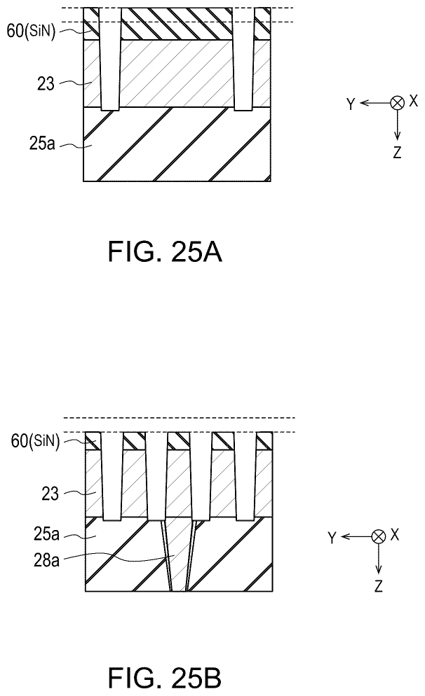

Next, the material of the insulating film 60 is processed using a lithography technique and an etching technique. Next, the material of the bit lines 23 is processed using the insulating film 60 as a mask. The bit lines 23 and the insulating films 60 are thereby formed as illustrated in FIGS. 25A and 25B. At that time, in the region of the stacked body 20 in FIG. 25B, the width between adjacent ones of the bit lines 23 is narrower and the bit lines 23 are in a denser state as compared to those in the peripheral region PD in FIG. 25A. Therefore, in the region of the stacked body 20, the insulating film 60 functioning as a hard mask is etched more than in the peripheral region PD. Accordingly, the height of the top surfaces of the insulating films 60 in the region of the stacked body 20 is lower than that in the peripheral region PD. Channels between adjacent ones of the bit lines 23 are formed to a position lower than the bottom surfaces of the bit lines 23.

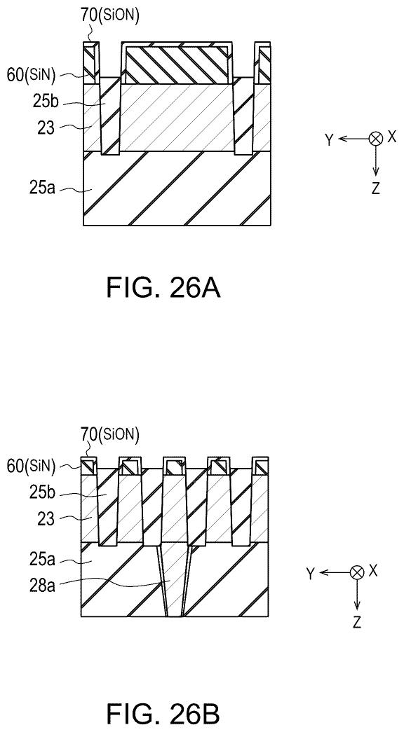

Next, as illustrated in FIGS. 26A and 26B, the insulating film 70 is formed on the top surface and the both side surfaces of each of the insulating films 60 by oxidizing the surfaces of the insulating films 60. That is, exposed surfaces (the top surface and the both side surfaces) of each of the insulating films 60 are oxidized to become the insulating film 70. For example, when the insulating film 60 is a silicon nitride film, the insulating film 70 is a silicon oxynitride film or a mixed film including a silicon dioxide film and a silicon oxynitride film.

Next, the material (for example, a silicon dioxide film) of the insulating film 25b is deposited in the channels between the bit lines 23 and on the insulating film 70. Next, as illustrated in FIGS. 26A and 26B, the material of the insulating film 25b is etched back to a position where the top surface of the insulating film 25b is lower than the top surfaces of the insulating films 70 and is higher than the bottom surfaces of the insulating films 60 or the insulating films 70. Accordingly, the top surface of the insulating film 25b between the bit lines 23 is located at a position lower than the top surface of the insulating film 70 and the top surfaces of the insulating films 25b and 70 include concaves and convexes as illustrated in FIG. 26B.

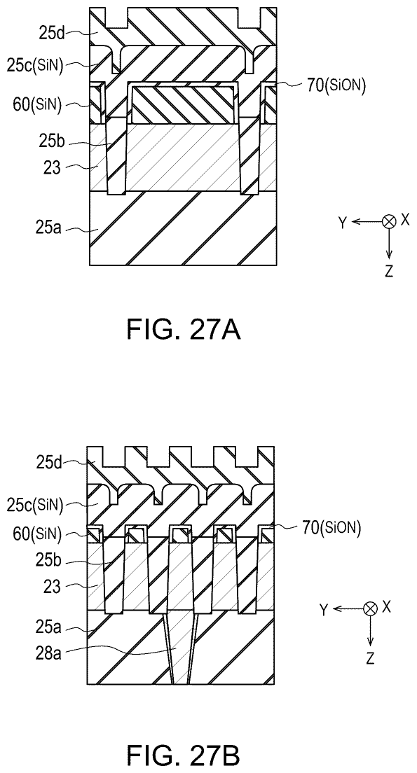

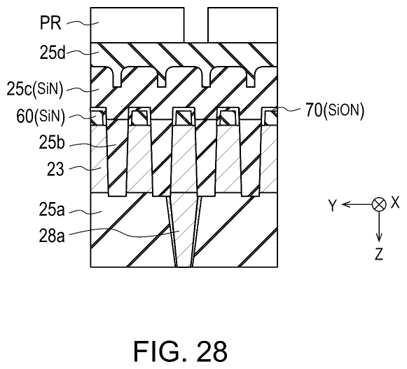

Next, as illustrated in FIGS. 27A and 27B, the insulating film 25c (for example, a silicon nitride film) and the insulating film 25d (for example, a silicon dioxide film) are deposited on the insulating film 70 and the insulating film 25b. The top surfaces of the insulating films 25c and 25d are formed in concave and convex shapes according to the concaves and convexes on the top surfaces of the insulating film 70 and the insulating film 25b. That is, the top surfaces of the insulating film 70 and the insulating film 25b are not flattened.

Next, as illustrated in FIG. 28, the top surface of the insulating film 25d is flattened using a CMP method or the like. Next, a photoresist PR is formed on the insulating film 25d using a lithography technique. The photoresist PR is processed to expose the insulating film 25d in the formation region of the via contacts 28b.

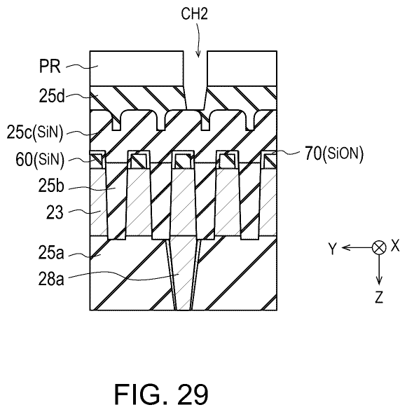

Next, as illustrated in FIG. 29, the insulating film 25d (for example, a silicon dioxide film) is anisotropically etched using the photoresist PR as a mask. At that time, the insulating film 25c (for example, a silicon nitride film) functions as an etching stopper.

The concaves and convexes on the top surfaces of the insulating films 25b and 70 are transferred also to the top surface of the insulating film 25c located thereon. The insulating film 25c on the bit lines 23 is protruded relative to other top surface regions of the insulating film 25c. Therefore, as illustrated in FIG. 29, when etching is stopped at a time when the insulating film 25c is exposed during etching of the insulating film 25d, the insulating film 25c on the bit lines 23 can be selectively exposed.

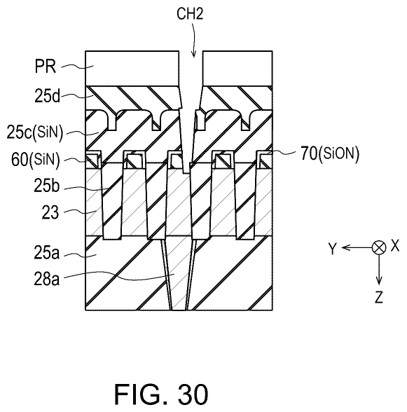

Next, as illustrated in FIG. 30, the insulating film 25c, the insulating film 70, and the insulating film 60 are anisotropically etched using the photoresist PR and the insulating film 25d as a mask. This causes the contact holes CH2 to penetrate through the insulating films 25d, 25c, 70, and 60 to reach the bit lines 23. At that time, the insulating film 25c above the bit lines 23 is selectively exposed. Therefore, the contact holes CH2 causes the insulating film 25c above the bit lines 23 to be selectively etched and further the insulating films 60 and 70 on the bit lines 23 to be selectively etched. Since being coated by the insulating film 25d, the insulating film 25c in the concave parts above the insulating film 25b between the bit lines 23 is hardly etched and is left. Accordingly, even when the photoresist PR is slightly misaligned, the contact holes CH2 can be formed in the upper parts of the bit lines 23 from the convex parts of the insulating film 25c on the bit lines 23. This leads to decrease in the parasitic capacitance PC2 between each of the via contacts 28b and the adjacent bit line 23.

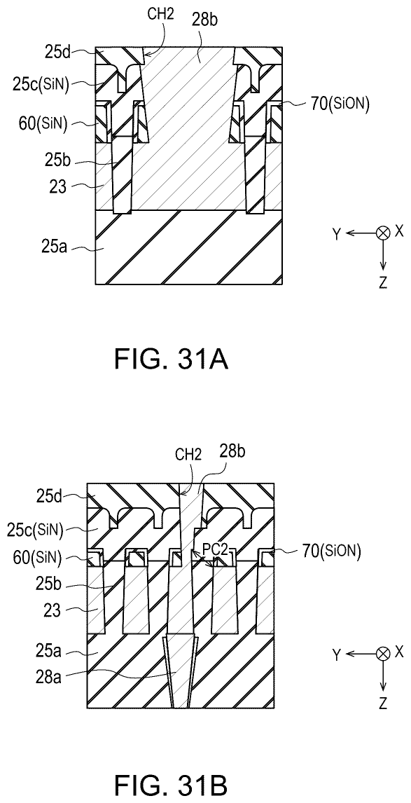

Next, the process explained with reference to FIG. 13 is performed, whereby each of the via contacts 28b is formed in the associated contact hole CH2 through the insulating films 25d, 25c, 70, and 60 to be connected to the top surface F23a of the associated bit line 23 as illustrated in FIGS. 31A and 31B. Each of the via contacts 28b is electrically connected to the semiconductor body 210 of any of the columnar bodies CL through the associated bit line 23. Meanwhile, in a region where the contact holes CH2 are not provided, the insulating films 25d, 25c, 60, and 70 remain on the bit lines 23.

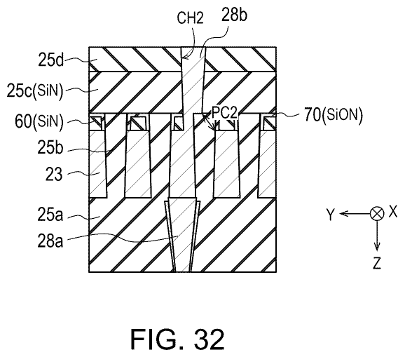

FIG. 32 is a sectional view illustrating a comparative example in a case in which the top surface of the insulating film 25c is flat. In this comparative example, the top surfaces of the insulating film 25b and the insulating film 60 are substantially flush with each other and, associated therewith, the top surface of the insulating film 25c is flat. In this case, when the photoresist PR is misaligned, the contact holes CH2 are formed in the insulating films 25d and 25c in accordance with the pattern of the photoresist PR and are selectively formed in the insulating film 60 on the bit lines 23. Since the insulating film 25c is etched in accordance with the pattern of the photoresist PR, the distance between each of the via contacts 28b and an adjacent bit line 23 becomes short as illustrated in FIG. 32. Therefore, the parasitic capacitance PC2 between each of the via contacts 28b and an adjacent bit line 23 is relatively large.

In contrast thereto, in the semiconductor device according to the fifth embodiment, the concaves and convexes on the top surfaces of the insulating films 25b and 60 are transferred also on the top surface of the insulating film 25c located thereon. The insulating film 25c on the bit lines 23 is protruded relative to other top surface regions of the insulating film 25c and the top surface of the insulating film 25c has concave and convex shapes. Accordingly, as illustrated in FIG. 29, when etching is stopped at a time when the insulating film 25c is exposed during etching of the insulating film 25d, the insulating film 25c on the bit lines 23 can be selectively exposed. As a result, the distance between each of the via contacts 28b and an adjacent bit line 23 can be formed longer than that in the comparative example. Therefore, the parasitic capacitance PC2 between each of the via contacts 28b according to the fifth embodiment and an adjacent bit line 23 can be decreased relative to that in the comparative example.

In the fifth embodiment, since the acceptable range of misalignment of the photoresist PR is enlarged, alignment in the lithography process becomes easy.

Other configurations and processes of the fifth embodiment may be identical to those of any of the other embodiments. Accordingly, the fifth embodiment can exert effects identical to those of any of the other embodiments.

While the embodiments described above are applied to bit lines of a memory, these embodiments can also be applied to lines other than the bit lines.

The array chip 2 according to the embodiments described above can be applied to semiconductor storage devices described below.

FIG. 33 is a block diagram illustrating a configuration example of a semiconductor storage device to which the array chip according to any of the embodiments described above is applied. The semiconductor storage device 1 is, for example, a memory 100a such as a NAND flash memory that can store data in a nonvolatile manner and is controlled by an external memory controller 1002. Communications between the memory 100a and the memory controller 1002 conform to, for example, NAND interface standards.

As illustrated in FIG. 33, the memory 100a includes, for example, a memory cell array MCA, a command register 1011, an address register 1012, a sequencer 1013, a driver module 1014, a row decoder module 1015, and a sense amplifier module 1016.

The memory cell array MCA includes a plurality of blocks BLK(0) to BLK (n) (n is an integer equal to or greater than one). Each of the blocks BLK is a set of a plurality of memory cells that can store data in a nonvolatile manner and is used as, for example, a unit of data erasing. A plurality of bit lines and a plurality of word lines are provided in the memory cell array MCA. Each of the memory cells is associated with, for example, one bit line and one word line. A detailed configuration of the memory cell array MCA will be described later.

The command register 1011 retains a command CMD received by the memory 100a from the memory controller 1002. The command CMD includes, for example, a command for causing the sequencer 1013 to perform an operation such as a read operation, a write operation, or an erase operation.

The address register 1012 retains address information ADD received by the memory 100a from the memory controller 1002. The address information ADD includes, for example, a block address BA, a page address PA, and a column address CA. For example, the block address BA, the page address PA, and the column address CA are used for selection of a block BLK, a word line, and a bit line, respectively.

The sequencer 1013 controls the entire operation of the memory 100a. For example, the sequencer 1013 controls the driver module 1014, the row decoder module 1015, the sense amplifier module 1016, or the like in accordance with the command CMD retained in the command register 1011 to perform an operation such as a read operation, a write operation, or an erase operation.

The driver module 1014 generates a voltage to be used in an operation such as a read operation, a write operation, or an erase operation. The driver module 1014 applies the generated voltage, for example, to a signal line corresponding to a word line selected in accordance with the page address PA that is retained in the address register 1012.

The row decoder module 1015 includes a plurality of row decoders. The row decoders select a corresponding one of the blocks BLK in the memory cell array MCA in accordance with the block address BA retained in the address register 1012. The row decoders transfer, for example, the voltage that is applied to the signal line corresponding to the selected word line, to the selected word line in the selected block BLK.

In a write operation, the sense amplifier module 1016 applies a desired voltage to each bit line according to data DAT to be written, which is received from the memory controller 1002. In a read operation, the sense amplifier module 1016 determines data stored in the memory cells on the basis of the voltages of the bit lines and transfers the determination result as read data DAT to the memory controller 1002.

A combination of the memory 100a and the memory controller 1002 described above may constitute one semiconductor storage device. A memory card such as an SD™ card and an SSD (solid state drive) are cited as examples of the semiconductor storage device.

FIG. 34 is a circuit diagram illustrating one example of the circuit configuration of the memory cell array MCA. One block BLK is extracted from the blocks BLK included in the memory cell array MCA. As illustrated in FIG. 34, each block BLK includes a plurality of string units SU(0) to SU (k) (k is an integer equal to or greater than one).

Each string unit SU includes a plurality of NAND strings NS each associated with one of bit lines BL(1) to BL (m) (m is an integer equal to or greater than one). Each NAND string NS includes, for example, memory cells MC(0) to MC(15), and selection transistors ST(1) and ST(2). Each memory cell MC includes a control gate and a charge capturing layer and retains data in a nonvolatile manner. Each of the selection transistors ST(1) and ST(2) is used to select a string unit SU at the time of various operations.

In each NAND string NS, the memory cells MC(0) to MC(15) are connected in series. The drain of the selection transistor ST(1) is connected to the associated bit line BL, and the source of the selection transistor ST(1) is connected to one end of the series-connected memory cells MC(0) to MC(15). The drain of the selection transistor ST(2) is connected to the other end of the series-connected memory cells MC(0) to MC(15). The source of the selection transistor ST(2) is connected to the source line SL.

The control gates of the memory cells MC(0) to MC(15) in a same block BLK are connected in common to the associated one of the word lines WL(0) to WL(15). The gates of the selection transistors ST(1) in each of the string units SU(0) to SU (k) are connected in common to the associated one of selection gate lines SGD(0) to SGD (k). The gates of the selection transistors ST(2) are connected in common to a selection gate line SGS.

In the circuit configuration of the memory cell array MCA described above, each of the bit lines BL is shared by the NAND strings NS to which a same column address is assigned in each of the string units SU. The source line SL is shared by, for example, a plurality of the blocks BLK.

A set of memory cells MC connected to a common word line WL in one string unit SU is referred to as, for example, “cell unit CU”. For example, the storage capacity of the cell unit CU including memory cells MC each storing one-bit data is defined as “one page data”. One cell unit CU can have the storage capacity of two or more page data according to the number of bits in data that is stored in one memory cell MC.

The memory cell array MCA included in the memory 100a according to the present embodiment is not limited to the circuit configuration described above. For example, the number of the memory cells MC and the number of the selection transistors ST(1) and ST(2) included in each of the NAND strings NS can each be designed to any number. The number of the string units SU included in each of the blocks BLK can be designed to any number.

The embodiments descried above can be applied to lines and via contacts of a logic circuit such as a CMOS chip as well as to the array chip of a memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a plurality of first lines located in a first direction with respect to a first insulating film, the first lines being arrayed in a second direction intersecting with the first direction and extending in a third direction intersecting with the first and second directions;
a plurality of second insulating films located correspondingly on the first lines, respectively, where a width of each of the second insulating films in the second direction in a face in contact with a corresponding first line is smaller than a width of the corresponding first line in the second direction;
a plurality of third insulating films located correspondingly on the first lines, respectively, arrayed in the second direction, extending in the third direction, and each coating at least both side surfaces of an associated one of the second insulating films;
a fourth insulating film located on the third insulating films;
a fifth insulating film located on the fourth insulating film;
a first contact penetrating through the second to fifth insulating films to be connected to any of the first lines; and
a second line located on the first contact, wherein
the first contact or at least the second and fourth insulating films are located in the first direction of the first lines.

2. The device of claim 1, wherein
the first, third, and fifth insulating films comprise silicon and oxygen, and
the second and fourth insulating films comprise silicon and nitrogen.

3. The device of claim 1, wherein each of the third insulating films coats a top surface of an associated one of the second insulating films and is located between the second insulating film and the fourth insulating film.

4. The device of claim 1, wherein the fourth insulating film coats the top surfaces of the second insulating films and is in contact with the second insulating films.

5. The device of claim 1, further comprising a sixth insulating film located between the first lines.

6. The device of claim 1, wherein air gaps are located between the first lines.

7. The device of claim 6, wherein top ends of the air gaps are located below top surfaces of the first lines.

8. The device of claim 6, wherein bottom ends of the air gaps are located below bottom surfaces of the first lines.

9. The device of claim 1, wherein the first contact comprises a step at a same height as a bottom surface of the fourth insulating film.

10. The device of claim 9, wherein a width of the first contact in the second or third direction at the same height as the bottom surface of the fourth insulating film is larger than a width of the first contact in the second or third direction in a connection face with an associated one of the first lines.

11. The device of claim 1, wherein a width of the first contact in the second or third direction in a connection face with an associated one of the first lines is smaller than a width of the first line in the second direction.

12. The device of claim 5, wherein the third insulating film is located on side surfaces of the first contact between the sixth insulating films adjacent in the second direction.

13. The device of claim 1, further comprising:
a stacked body comprising a plurality of first conducting films and a plurality of seventh insulating films alternately stacked in the first direction;
a plurality of columnar bodies each comprising a first semiconductor part extending in the first direction in the stacked body, and a first insulator part located between the first semiconductor part and the stacked body; and
a second contact penetrating through the first insulating film and connecting between the columnar bodies and the first lines.

14. The device of claim 1, wherein a top surface of the fourth insulating film has concave and convex shapes to be protruded in regions on the first lines.

15. The device of claim 5, wherein the top surfaces of the second insulating films are protruded relative to a top surface of the sixth insulating film.

16. A manufacturing method of a semiconductor device, the method comprising:
depositing a first line material and a second insulating film material in a first direction of a first insulating film;
processing the first line material and the second insulating film material to form a plurality of first lines and a plurality of second insulating films arrayed in a second direction intersecting with the first direction and extending in a third direction intersecting with the first and second directions;
oxidizing surfaces of the second insulating films to form a plurality of third insulating films at least on both side surfaces of each of the second insulating films;
forming a fourth insulating film on the third insulating films;
forming a fifth insulating film on the fourth insulating film;
forming a first contact penetrating through the second to fifth insulating films to be connected to any of the first lines, and causing at least the second and third insulating films to remain in a region where the first contact is not located in the first direction of the first lines; and
forming a second line on the first contact.

17. The method of claim 16, wherein
the forming the first contact further comprises:
processing the fifth insulating film according to a difference in an etching rate between the fourth and fifth insulating films to form a first contact hole;
selectively removing the second insulating films with respect to the third insulating films according to a difference in an etching rate between the second and third insulating films to form the first contact hole further to reach the first lines; and
forming a metallic material in the first contact hole to form the first contact.

18. The method of claim 16, further comprising:
forming a sacrificial film between the third insulating films after the third insulating films are formed;
etching the sacrificial film until a top surface of the sacrificial film is positioned below top surfaces of the first lines;
depositing an eighth insulating film on the sacrificial film; and
removing the sacrificial film.

19. The method of claim 16, wherein a top surface of the first insulating film is gouged to a position lower than bottom surfaces of the first lines during processing of the first line material and the second insulating film material.

20. The method of claim 16, comprising:
forming a sixth insulating film between adjacent ones of the first lines to a position lower than the second or third insulating film to cause the second or third insulating film to be protruded relative to the sixth insulating film after the first lines and the third insulating films are formed;
depositing the fourth insulating film on the third and sixth insulating films to cause a top surface of the fourth insulating film to include concaves and convexes according to concaves and convexes of the third and sixth insulating films; and
forming the fifth insulating film and the first contact without flattening the top surface of the fourth insulating film.
